(19) United States
(12) Patent Application Publication
(10) Pub. No.: US 2026/0107619 A1
(43) Pub. Date: Apr. 16, 2026

(54) ELECTRONIC DEVICE

(71) Applicant: CARUX TECHNOLOGY PTE. LTD., APERIA (SG)

(72) Inventors: Mei-Ying CHEN, Tainan (Tainan Science Park) (TW); Szu-Yen YU, Tainan (Tainan Science Park) (TW); Yen-Liang CHEN, Tainan (Tainan Science Park) (TW)

(21) Appl. No.: 19/328,486

(22) Filed: Sep. 15, 2025

(30) Foreign Application Priority Data
Oct. 16, 2024 (CN) 202411441675.X

(51) Int. Cl. H10H 29/855; H01L 25/075; H10H 29/80; H10H 29/856

(52) U.S. Cl. CPC H10H 29/855; H10H 29/856; H10H 29/882; H10W 90/00

(57) ABSTRACT

An electronic device is provided. The electronic device includes a substrate, a light-emitting unit, and a light-guide structure. The light-emitting unit is disposed on the substrate. The light-guide structure is disposed on the substrate and includes a main portion and a convex portion connected to each other. The main portion is disposed on the light-emitting unit. The convex portion is disposed between two adjacent light-emitting units. In a cross-sectional view, the distance between the convex portion and the light-emitting unit is greater than or equal to 0.5 mm and less than or equal to 5 mm.

### CROSS REFERENCE TO RELATED APPLICATIONS

This application claims priority of China Patent Application No. 202411441675.X, filed on Oct. 16, 2024, the entirety of which is incorporated by reference herein.

### BACKGROUND

### Technical Field

The present disclosure relates to an electronic device, and in particular it relates to an electronic device with a particular light-guide structure.

### Description of the Related Art

When the display unit of an electronic device is made thinner, the problem of bright spots may arise, resulting in uneven light emission. This problem can generally be solved by increasing the arrangement density of the LEDs. However, this solution is bound to increase manufacturing costs.

Therefore, it is imperative to develop a structural technology that can increase the uniformity of light emission while reducing the number of LEDs.

### SUMMARY

In accordance with one embodiment of the present disclosure, an electronic device is provided. The electronic device includes a substrate, a light-emitting unit, and a light-guide structure. The light-emitting unit is disposed on the substrate. The light-guide structure is disposed on the substrate and includes a main portion and a convex portion connected to each other. The main portion is disposed on the light-emitting unit. The convex portion is disposed between two adjacent light-emitting units. In a cross-sectional view, the distance between the convex portion and the light-emitting unit is greater than or equal to 0.5 mm and less than or equal to 5 mm.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a cross-sectional view of an electronic device in accordance with one embodiment of the present disclosure;

FIG. 2A shows a cross-sectional view of a light-guide structure in an electronic device in accordance with one embodiment of the present disclosure;

FIG. 2B shows a cross-sectional view of a light-guide structure in an electronic device in accordance with one embodiment of the present disclosure;

FIG. 2C shows a cross-sectional view of a light-guide structure in an electronic device in accordance with one embodiment of the present disclosure;

FIG. 2D shows a cross-sectional view of a light-guide structure in an electronic device in accordance with one embodiment of the present disclosure;

FIG. 3 shows a cross-sectional view of an electronic device in accordance with one embodiment of the present disclosure;

FIG. 4 shows a cross-sectional view of an electronic device in accordance with one embodiment of the present disclosure;

FIG. 5A shows a cross-sectional view of a light-guide structure in an electronic device in accordance with one embodiment of the present disclosure; and

FIG. 5B shows a side view of a light-guide structure in an electronic device in accordance with one embodiment of the present disclosure.

### DETAILED DESCRIPTION

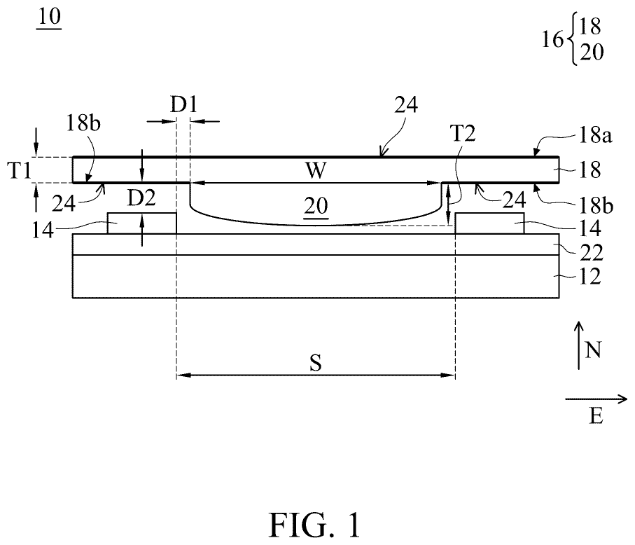

Referring to FIG. 1, in accordance with one embodiment of the present disclosure, an electronic device 10 is provided. FIG. 1 is a cross-sectional view of the electronic device 10.

As shown in FIG. 1, the electronic device 10 a substrate 12, a light-emitting unit 14 and a light-guide structure 16. The light-emitting unit 14 is disposed on the substrate 12. The light-guide structure 16 is disposed on the substrate 12. The light-guide structure 16 includes a main portion 18 and a convex portion 20 connected to each other. The main portion 18 is disposed on the light-emitting unit 14. The convex portion 20 is disposed between two adjacent light-emitting units 14. Here, the “two adjacent light-emitting units” is defined as adjacent light-emitting units in any direction. Therefore, the light-emitting units in a nine-square grid are counted as adjacent light-emitting units.

It is worth noting that, in a cross-sectional view (as shown in FIG. 1), the distance D1 between the convex portion 20 and the light-emitting unit 14 is greater than or equal to 0.5 mm and less than or equal to 5 mm. In accordance with some embodiments, the distance D1 between the convex portion 20 and the light-emitting unit 14 is greater than or equal to 1.5 mm and less than or equal to 4 mm. With an appropriate distance D1 between the convex portion 20 and the light-emitting unit 14, the electronic device has improved light-emitting effect and reliability. The distance D1 can be measured, for example, by taking a cross-sectional view and measuring the distance from the edge of the light-emitting unit 14 to the edge of the adjacent convex portion 20 in the extension direction E of the substrate 14. The measuring tools can be, for example, a ruler, a microscope, etc.

In accordance with some embodiments, the light-emitting unit 14 emits light from one side. In accordance with some embodiments, the light-emitting unit 14 emits light from multiple sides, for example, from four sides or from five sides, but the present disclosure is not limited thereto.

In accordance with some embodiments, the refractive index of the light-guide structure 16 is greater than or equal to 1 and less than or equal to 1.9. In accordance with some embodiments, the refractive index of the light-guide structure 16 is greater than or equal to 1.2 and less than or equal to 1.7. The measurement of the refractive index can be derived, for example, from Snell's law. When the refractive index is within an appropriate range, the light-guide structure 16 has an improved optical surface.

In accordance with some embodiments, the light transmittance of the light-guide structure 16 is greater than or equal to 20% and less than or equal to 99.8%. In accordance with some embodiments, the light transmittance of the light-guide structure 16 is greater than or equal to 30% and less than or equal to 90%.

The “light transmittance” mentioned in the present disclosure refers to a percentage of measured light intensity of transmitted light after a light source penetrates a component, structure or material divided by measured light intensity of the light source without penetrating a component, structure or material. The “light intensity” mentioned in the present disclosure refers to a spectrum integrated value of a light source (the light source may include, for example, display light or ambient light). The light source may, for example, include visible light (for example, with a wavelength between 380 nm and 780 nm), but the present disclosure is not limited thereto. For example, when the light source is visible light, the light intensity is the spectrum integrated value within the wavelength range of 380 nm to 780 nm. The light transmittance of the object to be measured is the percentage of the measured visible-light spectrum integrated value after the light source penetrates the object to be measured divided by the measured visible-light spectrum integrated value of the light source without penetrating the object to be measured. During measurement, the light transmittance of multiple points (for example, three points) can be measured and then averaged, or the average light transmittance within a selected area (for example, 1 mm²) can be measured, but the present disclosure is not limited thereto.

In accordance with some embodiments, in the normal direction N of the substrate 12, the thickness T1 of the main portion 18 is greater than or equal to 0.1 mm and less than or equal to 2.0 mm. In accordance with some embodiments, in the normal direction N of the substrate 12, the thickness T1 of the main portion 18 is greater than or equal to 0.5 mm and less than or equal to 1.6 mm. With an appropriate thickness of the main portion 18, the electronic device has improved light-emitting effect and reliability. The thickness T1 can be measured, for example, by taking a cross-sectional view and measuring the distance between the upper edge and the lower edge of the main portion 18 in the normal direction N of the substrate 14. The measuring tools can be, for example, a ruler, a microscope, etc.

In accordance with some embodiments, in the normal direction N of the substrate 12, the distance D2 between the main portion 18 and the light-emitting unit 14 is greater than or equal to 0.01 mm and less than or equal to 3.0 mm. In accordance with some embodiments, in the normal direction N of the substrate 12, the distance D2 between the main portion 18 and the light-emitting unit 14 is greater than or equal to 0.1 mm and less than or equal to 2.0 mm. With an appropriate distance D2 between the main portion 18 and the light-emitting unit 14, the electronic device has improved light-emitting effect and reliability. The distance D2 can be measured, for example, by taking a cross-sectional view and measuring the distance between the upper edge of the light-emitting unit 14 and the lower edge of the main portion 18 in the normal direction N of the substrate 14. The measuring tools can be, for example, a ruler, a microscope, etc.

In accordance with some embodiments, the main portion 18 includes an upper surface 18a and a lower surface 18b. The lower surface 18b of the main portion 18 corresponding to the light-emitting unit 14 has high roughness. When measuring the roughness of the surface, an area in a cross-sectional view of the surface can be randomly selected, and then multiple high points (such as but not limited to three high points) and multiple low points (such as but not limited to three low points) of the surface in the area are selected. The roughness of the surface can, for example, be defined as the average height difference between the selected high points and low points, but the present disclosure is not limited thereto. The cross-sectional view of the surface can be obtained, for example, by a scanning electron microscope (SEM), but the present disclosure is not limited thereto.

In accordance with some embodiments, the lower surface 18b of the main portion 18 corresponding to the light-emitting unit 14 has a geometric structure 24. In accordance with some embodiments, the geometric structure 24 provided on the lower surface 18b of the main portion 18 corresponding to the light-emitting unit 14 includes microstructures such as a matte surface, regular or irregular matte backcoating, or concave-convex patterns.

In accordance with some embodiments, the upper surface 18a of the main portion 18 has high roughness. “The upper surface 18a of the main portion 18 has high roughness” can, for example, have a higher roughness compared with the lower surface of the main portion 18, or have a higher roughness than other optical film surfaces, but the present disclosure is not limited thereto.

In accordance with some embodiments, the upper surface 18a of the main portion 18 has a geometric structure 24. In accordance with some embodiments, the geometric structure 24 provided on the upper surface 18a of the main portion 18 includes microstructures such as a matte surface, regular or irregular matte backcoating, or concave-convex patterns.

In accordance with some embodiments, in a cross-sectional view (as shown in FIG. 1), in the extension direction E of the substrate 12, the width W of the convex portion 20 is less than or equal to the spacing S between the two light-emitting units 14. In accordance with some embodiments, the spacing S between two adjacent light-emitting units 14 is greater than or equal to 5 mm and less than or equal to 15 mm. In accordance with some embodiments, the spacing S between two adjacent light-emitting units 14 is greater than or equal to 9 mm and less than or equal to 12 mm. The spacing S can be measured, for example, by taking a cross-sectional view and measuring the shortest distance between two adjacent light-emitting units 14 in the extension direction E of the substrate 14. The measuring tools can be, for example, a ruler, a microscope, etc.

In accordance with some embodiments, when the thickness T2 of the convex portion 20 is greater than or equal to half of the width W of the convex portion 20, the convex portion 20 has a light-concentrating structure. The light-concentrating structure includes, for example, a convex lens structure, but the present disclosure is not limited thereto.

In accordance with some embodiments, when the thickness T2 of the convex portion 20 is less than half of the width W of the convex portion 20, the convex portion 20 has a light-scattering structure. The light-scattering structure includes, for example, a concave lens structure, but the present disclosure is not limited thereto.

In accordance with some embodiments, the focal length of the convex portion 20 is greater than or equal to 0.1 mm and less than or equal to 10 mm. In accordance with some embodiments, the focal length of the convex portion 20 is greater than or equal to 0.1 mm and less than or equal to 15 mm. In accordance with some embodiments, the focal length of the convex portion 20 is greater than or equal to 1 mm and less than or equal to 8 mm. The electronic device can have improved light uniformity within the focal length range.

In the present disclosure, the measurement method of the focal length of the convex portion is as follows. When the convex portion 20 is a light-concentrating structure (for example, a convex lens), a parallel light is incident into the lens and the light is emitted from the other side. The distance between the light-concentrating point and the lens is measured, which is the focal length. When the convex portion 20 is a light-scattering structure (for example, a concave lens), a point light source enters the lens, and the light is emitted from the other side. When the point light source is moved so that there is a distance between the point light source and the lens, the light emitted from the other side of the lens is parallel light. At this time, the distance between the point light source and the lens is the focal length.

In accordance with some embodiments, in a top view (not shown), the convex portion 20 is dot-shaped, linear-shaped or strip-shaped.

In accordance with some embodiments, the main portion 18 and the convex portion 20 of the light-guide structure 16 can be made by injection molding (for example, single material or dual material) or by 3D printing in one step or in batches.

In accordance with some embodiments, the electronic device 10 further includes a reflective layer 22 disposed between the light-emitting unit 14 and the substrate 12.

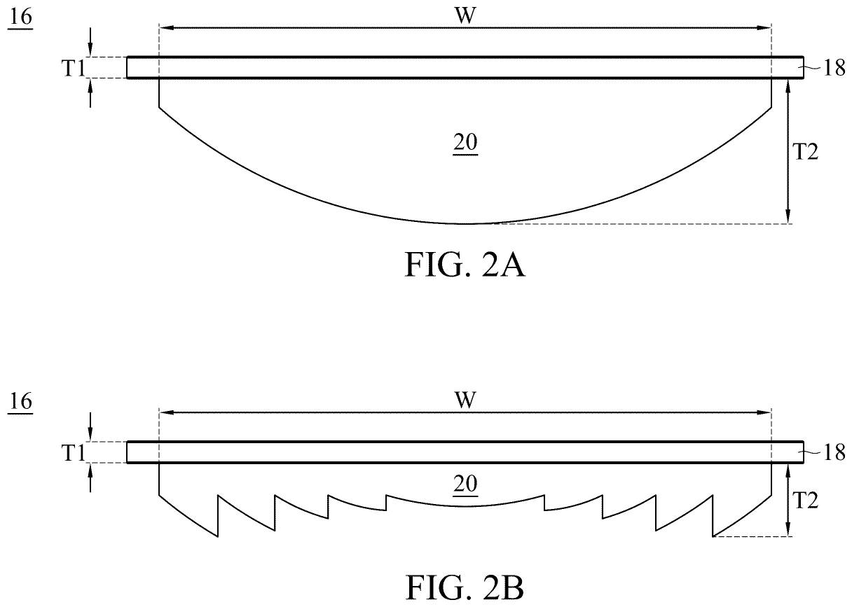

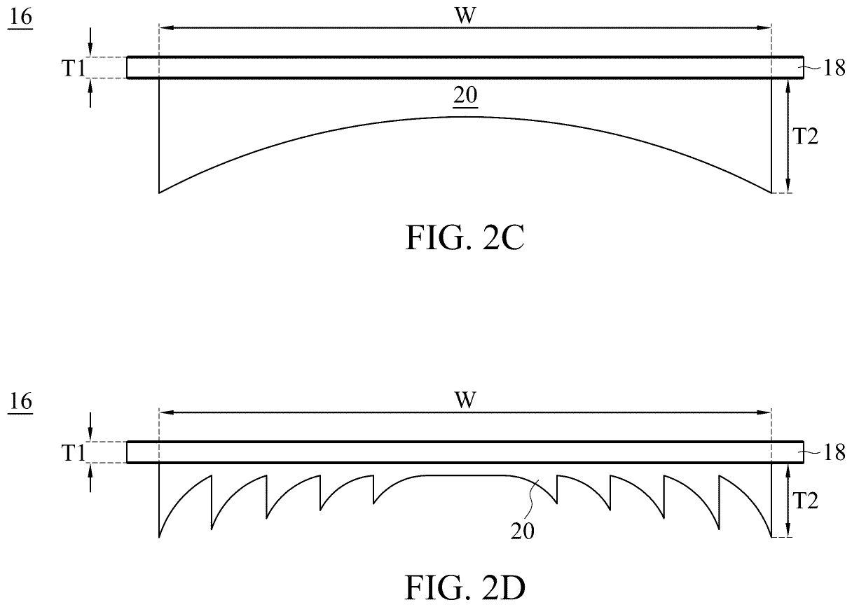

Referring to FIGS. 2A-2D, in accordance with one embodiment of the present disclosure, different profiles of the light-guide structures are provided. FIGS. 2A-2D are cross-sectional views of the light-guide structures in the electronic devices.

As shown in FIG. 2A, the light-guide structure 16 includes the main portion 18 and the convex portion 20 connected to each other.

In accordance with some embodiments, the thickness T1 of the main portion 18 is greater than or equal to 0.1 mm and less than or equal to 2.0 mm, but the present disclosure is not limited thereto.

In accordance with FIG. 2A, since the thickness T2 of the convex portion 20 is greater than or equal to half of the width W of the convex portion 20, the convex portion 20 is a light-concentrating structure, for example, a spherical lens as shown in FIG. 2A.

As shown in FIG. 2B, the light-guide structure 16 includes the main portion 18 and the convex portion 20 connected to each other.

In accordance with some embodiments, the thickness T1 of the main portion 18 is greater than or equal to 0.1 mm and less than or equal to 2.0 mm, but the present disclosure is not limited thereto.

In accordance with FIG. 2B, since the thickness T2 of the convex portion 20 is greater than or equal to half of the width W of the convex portion 20, the convex portion 20 is a light-concentrating structure, for example, a Fresnel lens that is an aspherical lens as shown in FIG. 2B. In some embodiments, the thickness T2 of the convex portion 20 may be, for example, greater than or equal to the distance from the upper surface of the light-emitting unit 14 to the lower surface of the main portion 18, or less than or equal to the distance from the upper surface of the light-emitting unit 14 to the lower surface of the main portion 18 plus 0.5 mm. Using a Fresnel lens as the convex portion 20 of the light-guide structure 16 can not only achieve the effect of thinning the structure, but also maintain the optical characteristics of a spherical lens (as shown in FIG. 2A).

As shown in FIG. 2C, the light-guide structure 16 includes the main portion 18 and the convex portion 20 connected to each other.

In accordance with some embodiments, the thickness T1 of the main portion 18 is greater than or equal to 0.1 mm and less than or equal to 2.0 mm, but the present disclosure is not limited thereto.

In accordance with FIG. 2C, since the thickness T2 of the convex portion 20 is less than half of the width W of the convex portion 20, the convex portion 20 is a light-scattering structure, for example, a concave lens as shown in FIG. 2C.

As shown in FIG. 2D, the light-guide structure 16 includes the main portion 18 and the convex portion 20 connected to each other.

In accordance with some embodiments, the thickness T1 of the main portion 18 is greater than or equal to 0.1 mm and less than or equal to 2.0 mm, but the present disclosure is not limited thereto.

In accordance with FIG. 2D, since the thickness T2 of the convex portion 20 is less than half of the width W of the convex portion 20, the convex portion 20 is a light-scattering structure, for example, a Fresnel lens as shown in FIG. 2D. Using a Fresnel lens as the convex portion 20 of the light-guide structure 16 can not only achieve the effect of thinning the structure, but also maintain the optical characteristics of a concave lens (as shown in FIG. 2C).

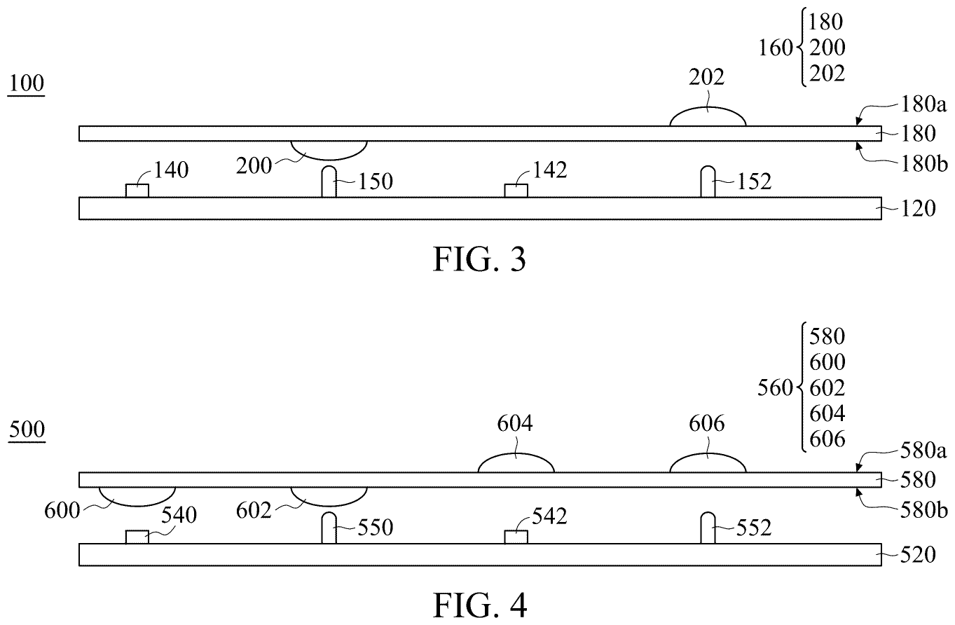

Referring to FIG. 3, in accordance with one embodiment of the present disclosure, an electronic device 100 is provided. FIG. 3 is a cross-sectional view of the electronic device 100.

The difference between the embodiment shown in FIG. 3 and the embodiment shown in FIG. 1 mainly lies in different designs of the light-guide structures in the electronic devices and configuration of additional retaining wall structures, which will be further described below. In FIG. 3, the remaining portions are similar to those disclosed in FIG. 1 and will not be repeated here.

As shown in FIG. 3, the electronic device 100 includes a substrate 120, a first light-emitting unit 140, a second light-emitting unit 142, a first retaining wall 150, a second retaining wall 152 and a light-guide structure 160. The first light-emitting unit 140 and the second light-emitting unit 142 are disposed on the substrate 120 and adjacent to each other. The first retaining wall 150 and the second retaining wall 152 are disposed on the substrate 120. The first retaining wall 150 is located between the first light-emitting unit 140 and the second light-emitting unit 142. The second retaining wall 152 is located on the other side of the second light-emitting unit 142 relative to the first retaining wall 150. The light-guide structure 160 is disposed on the substrate 120. The light-guide structure 160 includes a main portion 180 and a first convex portion 200 and a second convex portion 202 connected to the main portion 180. The main portion 180 includes an upper surface 180a and a lower surface 180b, and is disposed on the first light-emitting unit 140 and the second light-emitting unit 142. The first convex portion 200 is disposed on the lower surface 180b of the main portion 180, located between the adjacent first light-emitting unit 140 and the second light-emitting unit 142, and corresponds to the first retaining wall 150. The second convex portion 202 is disposed on the upper surface 180a of the main portion 180, located on the other side of the second light-emitting unit 142 relative to the first convex portion 200, and corresponds to the second retaining wall 152. In some embodiments, the first retaining wall 150 and the second retaining wall 152 include high-reflectivity surfaces, so that the electronic device has improved luminous efficiency. The high reflectivity can be, for example, 70% to 99%, but the present disclosure is not limited thereto.

In accordance with some embodiments, the first convex portion 200 and the second convex portion 202 include transparent high-refractive-index material. In accordance with some embodiments, in the first convex portion 200 and the second convex portion 202, scattering particles are mixed into the transparent high-refractive-index material so that the electronic device has improved luminous uniformity and luminous efficiency.

Referring to FIG. 4, in accordance with one embodiment of the present disclosure, an electronic device 500 is provided. FIG. 4 is a cross-sectional view of the electronic device 500.

The difference between the embodiment shown in FIG. 4 and the embodiment shown in FIG. 1 mainly lies in different designs of the light-guide structures in the electronic devices and configuration of additional retaining wall structures, which will be further described below. In FIG. 4, the remaining portions are similar to those disclosed in FIG. 1 and will not be repeated here.

As shown in FIG. 4, the electronic device 500 includes a substrate 520, a first light-emitting unit 540, a second light-emitting unit 542, a first retaining wall 550, a second retaining wall 552 and a light-guide structure 560. The first light-emitting unit 540 and the second light-emitting unit 542 are disposed on the substrate 520 and adjacent to each other. The first retaining wall 550 and the second retaining wall 552 are disposed on the substrate 520. The first retaining wall 550 is located between the first light-emitting unit 540 and the second light-emitting unit 542. The second retaining wall 552 is located on the other side of the second light-emitting unit 542 relative to the first retaining wall 550. The light-guide structure 560 is disposed on the substrate 520. The first retaining wall 550 and the second retaining wall 552 may be integrally formed with the substrate 520 when it is formed, for example. In some embodiments, the first retaining wall 550 and the second retaining wall 552 include polymer materials and can be formed on the substrate 520 by, for example, coating, dispensing glue, etc., but the present disclosure is not limited thereto. The light-guide structure 560 includes a main portion 580 and a first convex portion 600, a second convex portion 602, a third convex portion 604, and a fourth convex portion 606 connected to the main portion 580. The main portion 580 includes an upper surface 580a and a lower surface 580b, and is disposed on the first light-emitting unit 540 and the second light-emitting unit 542. The first convex portion 600 is disposed on the lower surface 580b of the main portion 580 and corresponds to the first light-emitting unit 540 (for example, located above the first light-emitting unit 540). The second convex portion 602 is disposed on the lower surface 580b of the main portion 580, located between the adjacent first light-emitting unit 540 and the second light-emitting unit 542, and corresponds to the first retaining wall 550. The third convex portion 604 is disposed on the upper surface 580a of the main portion 580 and corresponds to the second light-emitting unit 542 (for example, located above the second light-emitting unit 542). The fourth convex portion 606 is disposed on the upper surface 580a of the main portion 580, located on the other side of the second light-emitting unit 542 relative to the second convex portion 602, and corresponds to the second retaining wall 552.

In accordance with some embodiments, the first convex portion 600, the second convex portion 602, the third convex portion 604, and the fourth convex portion 606 include transparent high-refractive-index material. In accordance with some embodiments, in the first convex portion 600, the second convex portion 602, the third convex portion 604, and the fourth convex portion 606, scattering particles are mixed into the transparent high-refractive-index material.

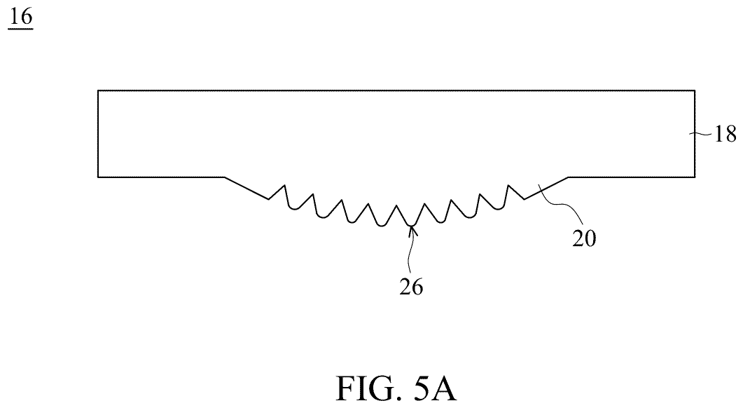

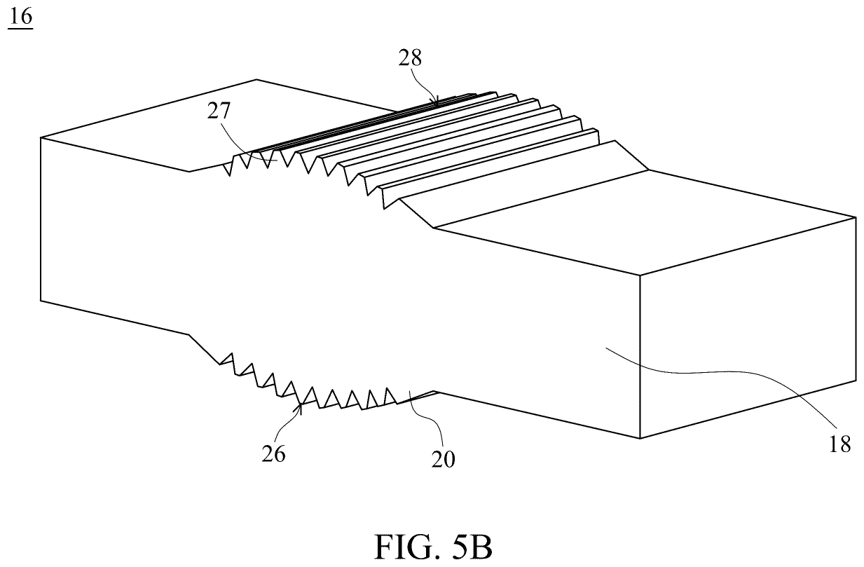

Referring to FIG. 5A, in accordance with one embodiment of the present disclosure, a light-guide structure is provided. FIG. 5A is a cross-sectional view of the light-guide structure in an electronic device.

As shown in FIG. 5A, the light-guide structure 16 includes a main portion 18 and a convex portion 20 connected to each other.

In order to increase light-incident ratio, a prism-like microstructure 26 is fabricated on the surface of the convex portion 20.

Referring to FIG. 5B, in accordance with one embodiment of the present disclosure, a light-guide structure is provided. FIG. 5B is a cross-sectional view of the light-guide structure in an electronic device.

As shown in FIG. 5B, the light-guide structure 16 includes a main portion 18 and a convex portion 20 connected to each other.

In accordance with FIG. 5B, in addition to fabricating the prism-like microstructure 26 on the surface of the convex portion 20, in order to further adjust the light emission from above, another convex portion 27 with a prism-like microstructure 28 on the surface thereof can also be made above the convex portion 20 (i.e. on the other side of the main portion 18 relative to the convex portion 20).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a substrate;
a light-emitting unit disposed on the substrate; and
a light-guide structure disposed on the substrate and comprising a main portion and a convex portion connected to each other, wherein the main portion is disposed on the light-emitting unit, and the convex portion is disposed between two adjacent light-emitting units,
wherein, in a cross-sectional view, a distance between the convex portion and the light-emitting unit is greater than or equal to 0.5 mm and less than or equal to 5 mm.

2. The electronic device as claimed in claim 1, wherein, in a cross-sectional view, a distance between the convex portion and the light-emitting unit is greater than or equal to 0.5 mm and less than or equal to 5 mm.

3. The electronic device as claimed in claim 1, wherein the light-guide structure has a refractive index that is greater than or equal to 1 and less than or equal to 1.9, and has a light transmittance that is greater than or equal to 20% and less than or equal to 99.8%.

4. The electronic device as claimed in claim 1, wherein, in a normal direction of the substrate, the main portion has a thickness that is greater than or equal to 0.1 mm and less than or equal to 2.0 mm.

5. The electronic device as claimed in claim 1, wherein, in a normal direction of the substrate, a distance between the main portion and the light-emitting unit is greater than or equal to 0.01 mm and less than or equal to 3.0 mm.

6. The electronic device as claimed in claim 1, wherein, in a cross-sectional view, in an extension direction of the substrate, the convex portion has a width that is less than or equal to a spacing between the two adjacent light-emitting units.

7. The electronic device as claimed in claim 6, wherein the spacing between the two adjacent light-emitting units is greater than or equal to 5 mm and less than or equal to 15 mm.

8. The electronic device as claimed in claim 1, further comprising a reflective layer disposed between the light-emitting unit and the substrate.

9. The electronic device as claimed in claim 1, wherein the main portion comprises an upper surface and a lower surface, and the lower surface corresponding to the light-emitting unit has a high roughness or a geometric structure.

10. The electronic device as claimed in claim 9, wherein the geometric structure comprises a matte surface, regular or irregular matte backcoating, or concave-convex patterns.

11. The electronic device as claimed in claim 9, wherein the upper surface has a high roughness or a geometric structure.

12. The electronic device as claimed in claim 1, wherein, when the convex portion has a thickness that is greater than or equal to half of a width of the convex portion, the convex portion is a light-concentrating structure.

13. The electronic device as claimed in claim 12, wherein the light-concentrating structure comprises a spherical lens.

14. The electronic device as claimed in claim 12, wherein the light-concentrating structure comprises a Fresnel lens.

15. The electronic device as claimed in claim 1, wherein, when the convex portion has a thickness that is less than half of a width of the convex portion, the convex portion is a light-scattering structure.

16. The electronic device as claimed in claim 15, wherein the light-scattering structure comprises a concave lens.

17. The electronic device as claimed in claim 15, wherein the light-scattering structure comprises a Fresnel lens.

18. The electronic device as claimed in claim 1, wherein the convex portion has a focal length that is greater than or equal to 0.1 mm and less than or equal to 15 mm.

19. The electronic device as claimed in claim 1, wherein, in a top view, the convex portion comprises a dot shape, a linear shape, or a strip shape.

20. The electronic device as claimed in claim 1, further comprising a retaining wall disposed on the substrate between the two adjacent light-emitting units and corresponding to the convex portion.
